(19) United States
(12) Patent Application Publication
(10) Pub. No.: US 2013/0128468 A1
(43) Pub. Date: May 23, 2013

(54) ELECTRONIC DEVICE WITH DOUBLE CIRCUIT BOARDS

(71) Applicants: GUANG-YI ZHANG, Shenzhen City (CN); MENG-QI ZHANG, Shenzhen City (CN)

(72) Inventors: GUANG-YI ZHANG, Shenzhen City (CN); MENG-QI ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/315,296

(22) Filed: Dec. 9, 2011

(30) Foreign Application Priority Data
Nov. 18, 2011 (CN) 201110367867.7

(51) Int. Cl. H05K 1/14

(52) U.S. Cl. 361/740

(57) ABSTRACT

A double circuit board module includes a bracket, a movable rack movably mounted to the bracket, a first circuit board fixed to the bracket, and a second circuit board fixed to the movable rack. After the movable rack is moved away from the bracket, the first circuit board is exposed.

### CROSS-REFERENCE TO RELATED APPLICATION

Relevant subject matter is disclosed in a pending U.S. patent application with application Ser. No. 13/298,307 (Docket No. US41816), filed on Nov. 17, 2011 and entitled “ELECTRONIC DEVICE WITH DOUBLE CIRCUIT BOARDS”, which is assigned to the same assignee as this patent application.

### BACKGROUND

1. Technical Field

The present disclosure relates to electronic devices, and particularly, to an electronic device with double circuit boards.

2. Description of Related Art

Electronic devices, such as servers, usually use double circuit boards to expand functions. However, the double circuit boards often make the cable arrangement and the electronic device repair difficult.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an electronic device, in accordance with an embodiment, wherein the electronic device includes a double circuit board module.

FIG. 2 is an exploded, isometric view of the double circuit board module of FIG. 1.

FIG. 3 is a partially assembled, isometric view of FIG. 2.

FIG. 4 and FIG. 5 are assembled, isometric views of FIG. 2, but show different using states of the double circuit board module.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

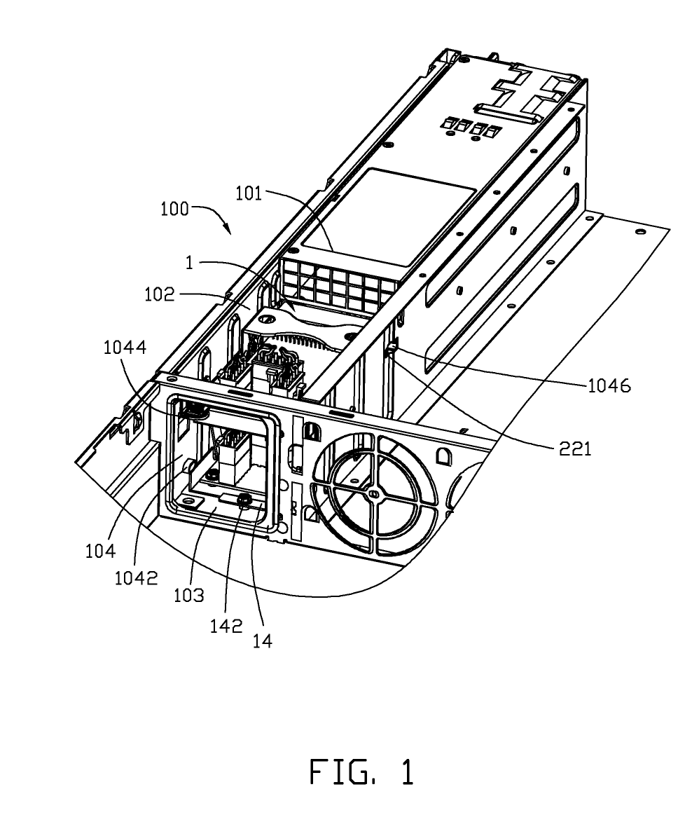

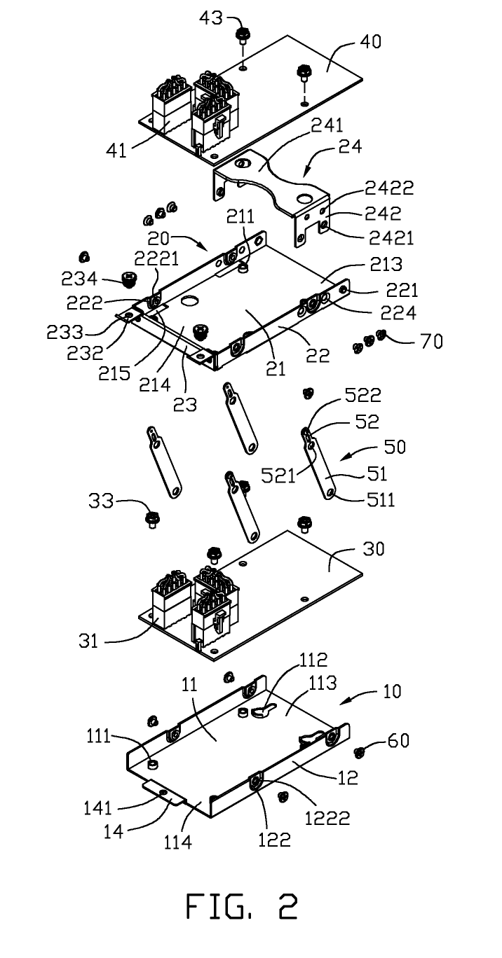

Referring to FIGS. 1 and 2, an exemplary embodiment of an electronic device 100 includes a chassis 101, and a double circuit board module 1 accommodated in the chassis 101. The double circuit board 1 includes a bracket 10, a movable rack 20, a first circuit board 30, a second circuit board 40, and a plurality of supporting members 50.

The chassis 101 includes a receiving space 102 for receiving the double circuit board module 1. The receiving space 102 includes a bottom wall 103 and two opposite sidewalls 104 respectively extending from opposite sides of the bottom wall 103. The bottom wall 103 defines a screw hole (not shown). Two posts (not shown) protrude from the bottom wall 103. A limiting block 1042 protrudes into the receiving space 102 from a first end of each sidewall 104. A mounting piece 1044 extends from each sidewall 104 above the limiting block 1042. An elongated slot 1046 is defined in a second end of each sidewall 104.

The bracket 10 includes a rectangular base plate 11, and two side plates 12 perpendicularly extending up from two opposite sides of the base plate 11. A plurality of posts 111 protrudes from the base plate 11. The base plate 11 includes a first end 113 and a second end 114 opposite to the first end 113. Two locking slots 112 are defined in the base plate 11 adjacent to the first end 113. A mounting piece 14 extends from the second end 114. The mounting piece 14 defines a mounting hole 141 for movably arranging a thumbscrew. Two raised portions 122 extend inward from each side plate 12. Each raised portion 122 defines a pivot hole 1222.

The rack 20 includes a base plate 21, two side plates 22 perpendicularly extending up from two opposite sides of the base plate 21, and an end plate 23 extending up from an end of the base plate 21 and connected between the side plates 22. A plurality of posts 211 protrudes from the base plate 21. The base plate 21 includes a first end 213 and a second end 214 opposite to the first end 213. A rod 221 extends outward from each side plate 22 adjacent to the first end 213. Two raised portions 222 extend inward from each side plate 22. Each raised portion 222 defines a pivot hole 2221. Two mounting holes 224 are defined in each side plate 22 beside one of the raised portions 222 adjacent to the first end 213. The end plate 23 extends from the second end 214. Two mounting pieces 232 extend respectively from opposite ends of the end plate 23. Each mounting piece 232 defines a mounting hole 233 for movably arranging a thumbscrew 234. A through slot 215 is defined in the base plate 21 adjacent to each raised portion 222.

A substantially U-shaped operation member 24 is fixed to the side plates 22. The operation member 24 includes an operation portion 241 and two positioning portions 242 extending down from opposite ends of the operation portion 241. Each positioning portion 242 defines two fixing holes 2421 corresponding to the mounting holes 224. Two positioning holes 2422 are defined in each positioning portion 242 above the mounting holes 224. A plurality of screws 70 is screwed into the mounting holes 224 and the fixing holes 2421 to fix the operation member 24 to the side plates 22.

The first circuit board 30 includes a plurality of connectors 31. A plurality of screws 33 extends through the first circuit board 30. The second circuit board 40 includes a plurality of connectors 41. A plurality of screws 43 extends through the second circuit board 40.

Each supporting member 50 is a substantially elongated piece, and includes a first end 51 and a second end 52 opposite to the first end 51. A first pivot hole 511 is defined in the first end 51. A second pivot hole 521 is defined in the supporting member 50 adjacent to the second end 52. A positioning protrusion 522 protrudes from the second end 52.

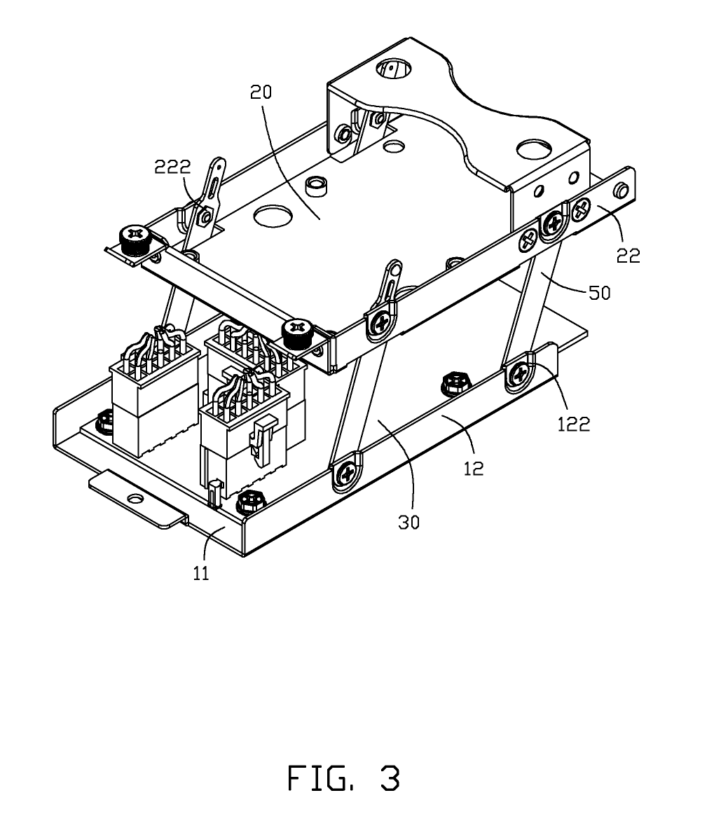

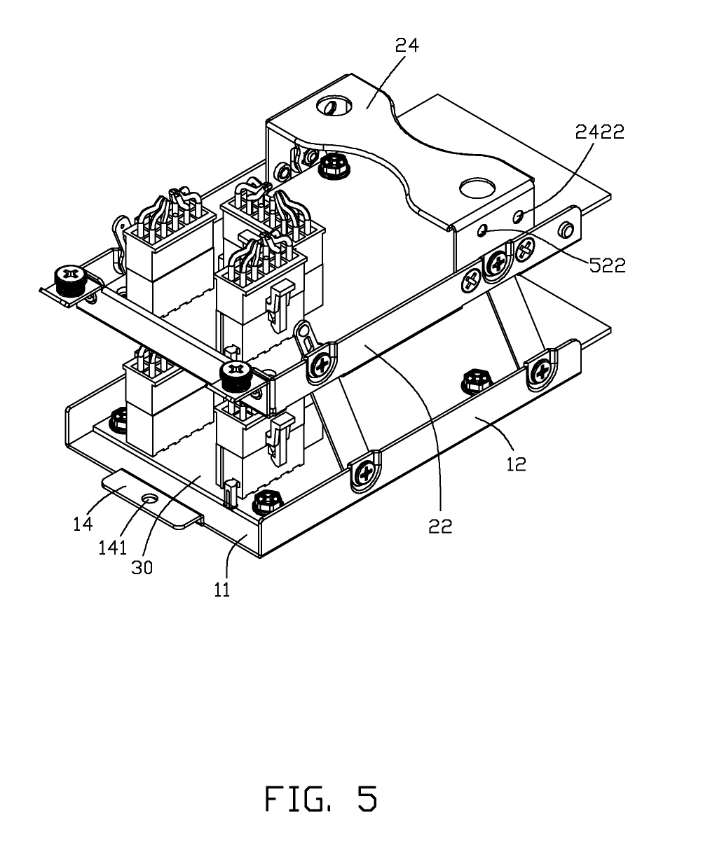

Referring to FIG. 3 to FIG. 5, in assembling the double circuit board module 1, the first circuit board 30 is placed in the bracket 10 and is fixed to the base plate 11 through the screws 33 screwing into the corresponding posts 111. A plurality of screws 60 respectively extends through the pivot holes 1222 and the first pivot holes 511 to pivotably mount the first ends 51 to the side plates 12. The second ends 52 respectively extend through the through slots 215. A plurality of another screws 60 respectively extends through the pivot holes 2221 and the second pivot holes 521 to pivotably mount the second ends 52 to the side plates 22. The second circuit board 40 is fixed to the base plate 21 through the screws 43 screwing into the posts 211.

Referring to FIG. 1, the double circuit board module 1 is arranged in the receiving space 102. The posts of the bottom wall 103 respectively engage in the locking slots 112. A thumbscrew 142 extends through the mounting hole 141 to screw in the bottom wall 103. The limiting blocks 1042 abut against tops of the sidewalls 12. The rods 221 movably engage in the corresponding slots 1046. The rack 20 is moved to make each positioning protrusion 522 engage in one of the corresponding positioning holes 2422. The thumbscrews 234 are screwed into the corresponding mounting pieces 1044.

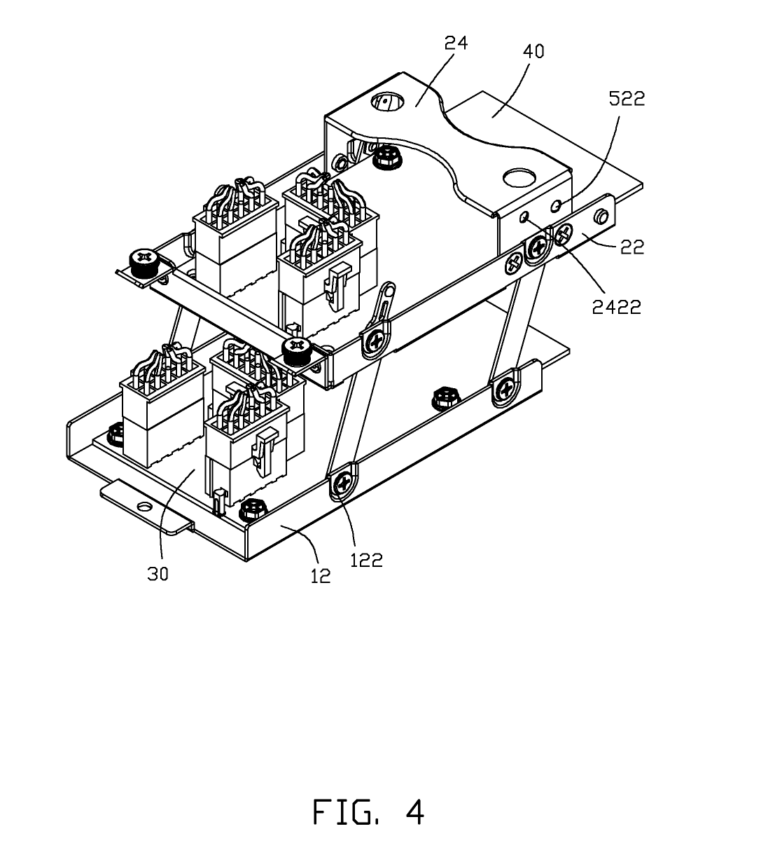

Referring to FIG. 4, when needing to operate the connectors 31 of the first circuit board 30, the thumbscrews 234 are released from the mounting pieces 1044 to move the rack 20 relative to the bracket 10 via pivoting of the plurality of supporting members 50 relative to the bracket 10 and the movable rack 20, until each positioning protrusion 522 engages in the other corresponding positioning hole 2422. Thereby, the first circuit board 30 is exposed to be conveniently operated.

It is believed that the present embodiments and theirs advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A double circuit board module comprising:
a bracket;
a movable rack;
a first circuit board fixed to the bracket;
a second circuit board fixed to the movable rack; and
a plurality of supporting members each comprising a first end and a second end respectively pivotably connected to the bracket and the rack,
wherein the movable rack moves relative to the bracket via pivoting of the plurality of supporting members relative to the bracket and the movable rack.

2. The double circuit board module of claim 1, wherein the bracket comprises a base plate and two side plates extending up from two opposite sides of the base plate, the first circuit board is fixed to the base plate, the first end of each of the supporting members is pivotably attached to a corresponding side plate of the bracket.

3. The double circuit board module of claim 2, wherein a plurality of posts protrudes from the base plate of the bracket, the first circuit board is fixed to the base plate through a plurality of screws extending through the first circuit board to screw into the posts.

4. The double circuit board module of claim 1, wherein each of the side plates of the bracket forms two raised portions, each of the raised portions defines a pivot hole for pivotably connecting the first end of the corresponding supporting member.

5. The double circuit board module of claim 1, wherein the rack comprises a base plate and two side plates extending up from opposite sides of the base plate, a plurality of posts protrudes from the base plate, the second circuit board is fixed to the base plate through a plurality of screws extending through the second circuit board to screw into the posts.

6. The double circuit board module of claim 5, wherein each of the side plates of the rack forms two raised portions, each of the raised portions defines a pivot hole for pivotably connecting the second end of the corresponding supporting member.

7. The double circuit board module of claim 6, wherein the base plate of the rack defines a through slot adjacent to each of the raised portions, the second end of the corresponding supporting member extends through the through slot and is pivotably connected to the corresponding raised portion.

8. The double circuit board module of claim 5, wherein an operation member is fixed to the rack, the operation member comprises an operation portion and two positioning portions extending from opposite ends of the operation portion, the positioning portions are fixed to the corresponding side plates of the movable rack.

9. The double circuit board module of claim 8, wherein two positioning holes are defined in each of the positioning portions, a positioning protrusion protrudes from the second end of each of the supporting member, for selectively engaging in one of the positioning holes.

10. An electronic device comprising:
a chassis; and
a double circuit board module arranged in the chassis, the double circuit module comprising:
a bracket;
a movable rack;
a first circuit board fixed to the bracket;
a second circuit board fixed to the movable rack; and
a plurality of supporting members each comprising a first end and a second end respectively pivotably connected to the bracket and the rack;
wherein the movable rack moves relative to the bracket via pivoting of the plurality of supporting members relative to the bracket and the movable rack.

11. The electronic device of claim 10, wherein the chassis comprises a bottom wall and two opposite sidewalls extending from opposite sides of the bottom wall, the bottom wall defines a screw hole, the bracket comprises a first base plate and two first side plates extending from opposite sides of the first base plate, a mounting piece extends from a first end of the first base plate, a thumbscrew is movably attached to the mounting piece and screwed into the screw hole of the bottom wall.

12. The electronic device of claim 11, wherein a limiting block protrudes from a first end of each of the sidewalls, for abutting against a top of one of the first side plates of the bracket.

13. The electronic device of claim 12, wherein a mounting piece extends from each of the sidewalls above the limiting block, the rack comprises a second base plate, two second side plates extending from opposite sides of the second base plate, and an end plate connected between the second side plates, two mounting pieces extend respectively from opposite ends of the end plate, each of the mounting pieces is movably attached with a thumbscrew to screw into a corresponding mounting piece of the sidewalls.

14. The electronic device of claim 10, wherein the bracket comprises a base plate and two side plates extending up from two opposite sides of the base plate, the first circuit board is fixed to the base plate, the first end of each of the supporting members is pivotably attached to a corresponding side plate.

15. The electronic device of claim 10, wherein each of the side plates of the bracket forms two raised portions, each of the raised portions defines a pivot hole for pivotably connecting the first end of the corresponding supporting member.

16. The electronic device of claim 10, wherein the rack comprises a base plate and two side plates extending from opposite sides of the base plate, a plurality of posts protrude from the base plate, the second circuit board is fixed to the base plate through a plurality of screws extending through the second circuit board to screw into the posts.

17. The electronic device of claim 16, wherein each of the side plates of the rack forms two raised portions, each of the raised portions defines a pivot hole for pivotably connecting the second end of the corresponding supporting member.

18. The electronic device of claim 17, wherein the base plate of the rack defines a through slot adjacent to each of the raised portions, the second end of the corresponding supporting member extends through the through slot and is pivotably connected to the corresponding raised portion.

19. The electronic device of claim 16, wherein an operation member is fixed to the rack, the operation member comprises an operation portion and two positioning portions extending from opposite ends of the operation portion, the positioning portions are fixed to the corresponding side plates of the movable rack.

20. The electronic device of claim 19, wherein two positioning holes are defined in each of the positioning portions, a positioning tab protrudes from the second end of each of the supporting member, for selectively engaging in one of the positioning holes.
